(19) United States
(12) Patent Application Publication
(10) Pub. No.: US 2020/0044090 A1
(43) Pub. Date: Feb. 6, 2020

(54) THIN FILM TRANSISTOR SUBSTRATE AND METHOD FOR MANUFACTURING SAME

(71) Applicant: Mitsubishi Electric Corporation, Chiyoda-ku, Tokyo (JP)

(72) Inventors: Takeo FURUHATA, Tokyo (JP); Toshiaki FUJINO, Tokyo (JP); Kazunori INOUE, Kumamoto (JP)

(73) Assignee: Mitsubishi Electric Corporation, Chiyoda-ku, Tokyo (JP)

(21) Appl. No.: 16/476,343

(22) PCT Filed: Nov. 15, 2017
(86) PCT No.: PCT/JP2017/041050

§ 371 Date: Jul. 8, 2019

(30) Foreign Application Priority Data
Apr. 3, 2017 (JP) 2017-073405

(51) Int. Cl. H01L 29/786; H01L 29/66; H01L 27/32

(52) U.S. Cl. CPC H01L 29/7869; H01L 27/3258; H01L 29/66969

(57) ABSTRACT

The purpose of the present invention is to provide a technique with which it is possible to suppress light having a harmful wavelength from reaching an active layer. A thin film transistor substrate includes: an active layer which is disposed on a gate insulating film, overlaps with a gate electrode in plan view, and contains an oxide semiconductor; a source electrode and a drain electrode, each connected to the active layer; a protective insulating film disposed on the active layer, the source electrode, and the drain electrode; and a pixel electrode disposed on an insulating film that includes the gate insulating film or the gate insulating film and the protective insulating film, and above the absorption layer, the pixel electrode being connected to the drain electrode.

### TECHNICAL FIELD

The present invention relates to a thin film transistor substrate and a method for manufacturing the same.

### BACKGROUND ART

Liquid crystal display (LCD) apparatuses, which are one of conventional common thin panels, are widely used for monitors of personal computers or portable information terminals by taking advantages of their low power consumption, small size, and light weight. Recently, liquid crystal display apparatuses are also widely used for TVs.

In addition, in order to address limitation of viewing angle and contrast or difficulty in following a high-speed response for a moving image, which is a problem of liquid crystal display apparatuses, EL (Electro-Luminescence) display apparatuses using light-emitters such as EL elements as pixels have also been used as next-generation thin panel devices. Note that EL elements are self-luminous, and have features which are not found in liquid crystal display apparatuses, such as a wide viewing angle, high contrast, and high-speed response.

For thin film transistors (TFTs) used in the display apparatuses described above, a MOS (Metal Oxide Semiconductor) structure using a semiconductor layer as a channel layer (active layer) is often used. There are various types of MOS thin film transistors, such as an inverted staggered structure (bottom gate structure) and a top gate structure. Further, an amorphous Si film or a polycrystalline Si film is used for the channel layer. For example, in a small display panel, a polycrystalline Si film is often used from the viewpoint of improvement of an aperture ratio of a display region, improvement of resolution, and necessity of configuring peripheral drive circuits such as a gate driver with thin film transistors. However, in recent years, an InGaZnO-based oxide semiconductor layer which has higher mobility than amorphous silicon and which can be deposited at low temperature is increasingly used as a channel layer of a thin film transistor. The oxide semiconductor layer can be formed by a sputtering method.

The thin film transistor used in the display apparatus is disposed on a transparent substrate such as a glass substrate, and is used while constantly receiving light from a backlight. A white LED (Light Emitting Diode) is generally used as a backlight, and the emission spectrum of the white LED has a strong peak near a wavelength of 450 nm.

On the other hand, the InGaZnO-based oxide semiconductor layer has an energy band gap of, for example, about 3.1 eV, and thus, it is transparent to visible light. However, in the energy band, a level that generates carriers by being excited by light near a wavelength of 450 nm is present. The generated carriers cause characteristic variation and characteristic fluctuation of the thin film transistor.

In view of this, in order to suppress the influence of the light irradiation as described above, that is, the characteristic variation and the characteristic fluctuation of the thin film transistor, various efforts are made for suppressing light incidence on the semiconductor layer. For example, in the technique disclosed in Patent Document 1, a light shielding layer made of an oxide semiconductor is disposed on an active layer.

### PRIOR ART DOCUMENTS

### Patent Documents

Patent Document 1: Japanese Patent Application No. 2012-222176

### SUMMARY

### Problem to be Solved by the Invention

However, in the technique disclosed in Patent Document 1 in which the light shielding layer is disposed on the active layer as described above, light directly entering the active layer through the gap between gate electrodes cannot be shielded. Further, there is, for example, light which is reflected at the interface of each layer in the TFT and enters the active layer from the side, so that there is a problem of insufficient light shielding performance.

The present invention is accomplished in view of the above problems, and aims to provide a technique with which it is possible to prevent light of a harmful wavelength from reaching an active layer.

### Means to Solve the Problem

A thin film transistor substrate according to the present invention includes: a substrate; a gate electrode disposed on the substrate; an absorption layer disposed on the substrate so as to be separated from the gate electrode and containing an oxide semiconductor; a gate insulating film disposed on the gate electrode and the absorption layer; an active layer disposed on the gate insulating film, overlapping with the gate electrode in plan view, and containing an oxide semiconductor; a source electrode and a drain electrode, each connected to the active layer; a protective insulating film disposed on the active layer, the source electrode, and the drain electrode; and a pixel electrode disposed on an insulating film that includes the gate insulating film or the gate insulating film and the protective insulating film, and above the absorption layer, the pixel electrode being connected to the drain electrode.

### Effects of the Invention

According to the present invention, an absorption layer which is provided on a substrate so as to be separated from a gate electrode and which includes an oxide semiconductor is provided. Thus, light harmful to the active layer can be effectively absorbed by the absorption layer, which can prevent the light from reaching the active layer.

The objects, features, aspects, and advantages of the present invention will become more apparent from the following detailed description and the accompanying drawings.

### BRIEF DESCRIPTION OF DRAWINGS

FIG. 1 is a plan view schematically showing the entire configuration of a thin film transistor substrate according to first to third embodiments.

FIG. 2 is a plan view showing an example of another configuration of a liquid crystal display apparatus provided with the thin film transistor substrate according to the first to third embodiments.

FIG. 3 is a plan view showing an example of the configuration of a liquid crystal display apparatus provided with the thin film transistor substrate according to the first embodiment.

FIG. 4 is a plan view showing an example of a spectrum of a backlight.

FIG. 5 is a sectional view showing an example of the configuration of the thin film transistor substrate according to the first embodiment.

FIG. 6 is a plan view showing an example of the configuration of an absorption layer according to the first embodiment.

FIG. 7 is a plan view showing an example of reflectance characteristics of an InGaZnO film.

FIG. 8 is a flowchart showing an example of a method for manufacturing the thin film transistor substrate according to the first embodiment.

FIG. 9 is a sectional view showing an example of the configuration of the thin film transistor substrate according to the second embodiment.

FIG. 10 is a sectional view showing an example of the configuration of the thin film transistor substrate according to the third embodiment.

### DESCRIPTION OF EMBODIMENTS

Thin film transistors (TFTs) provided in semiconductor devices according to first to third embodiments of the present invention described below are used as switching devices. Note that the TFTs can be applied to, for example, switching devices for pixels and drive circuits provided in flat panel display apparatuses (flat panel displays) such as liquid crystal display apparatuses and electroluminescence (EL) display apparatuses.

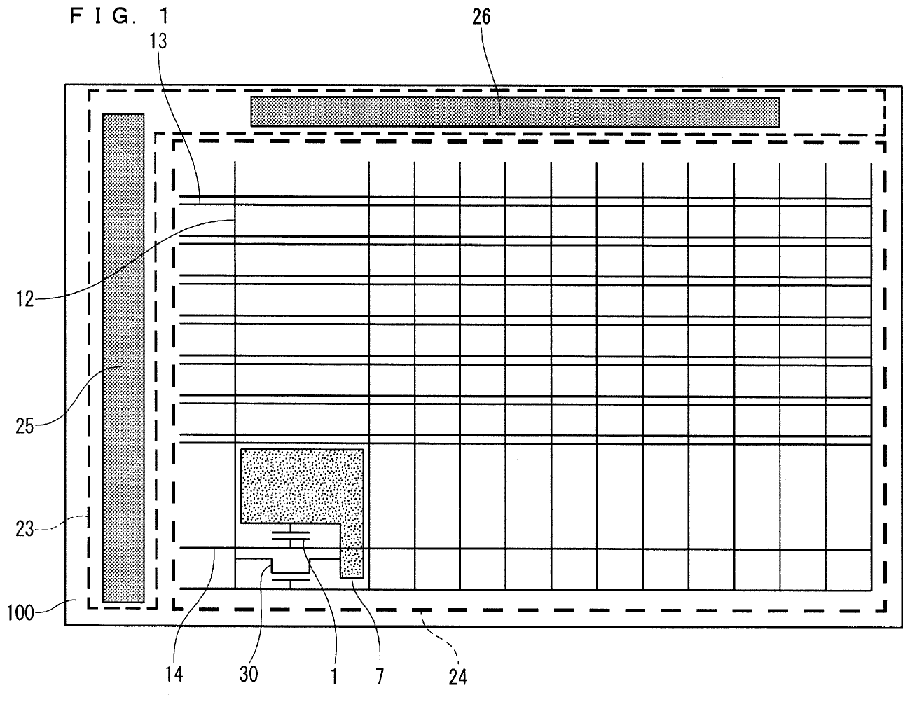

FIG. 1 is a plan view schematically showing the entire configuration of a TFT substrate 100 which is a thin film transistor substrate. As shown in FIG. 1, a display region 24 in which pixels (pixel regions) including pixel TFTs 30 are arranged in a matrix and a frame region 23 provided around the display region 24 so as to surround the display region 24 are defined in the TFT substrate 100.

In the display region 24, a plurality of source lines 12 and a plurality of gate lines 13 are disposed to intersect at right angles, and the pixel regions including the pixel TFTs 30 and pixel electrodes are provided at the intersections of the source lines 12 and the gate liens 13.

A scanning signal drive circuit 25 for applying a drive voltage to the gate lines 13 and a display signal drive circuit 26 for applying a drive voltage to the source lines 12 are provided in the frame region 23. Note that, in FIG. 1, the connection between the gate lines 13 and the scanning signal drive circuit 25 and a portion of the connection between the source lines 12 and the display signal drive circuit 26 are not shown in detail.

When a current flows selectively through one gate line 13 by the scanning signal drive circuit 25 and a current flows selectively through one source line 12 by the display signal drive circuit 26, the pixel TFT 30 of the pixel at the intersection of these lines is turned on, and charges are accumulated in the pixel electrode connected to the pixel TFT 30.

In the first and second embodiments described below, an absorption layer 1 which is a light shielding layer is used as a common electrode for forming an electric field with a pixel electrode 7, and a light shielding layer connection line 14 is connected to the absorption layer 1. Meanwhile, in the third embodiment to be described later, the absorption layer 1 which is a light shielding layer is used as a storage capacitor electrode which assists the storage of charges in the pixel electrode 7.

The following methods are conceivable for the connection between the absorption layer 1 and an extraction electrode for applying a voltage to the absorption layer 1. One of them is a method for forming an electrically connected extraction electrode (not shown) through a contact hole on the absorption layer 1 in a terminal part defined in the frame region 23 or the like, and connecting the extraction electrode and the absorption layer 1 to each other.

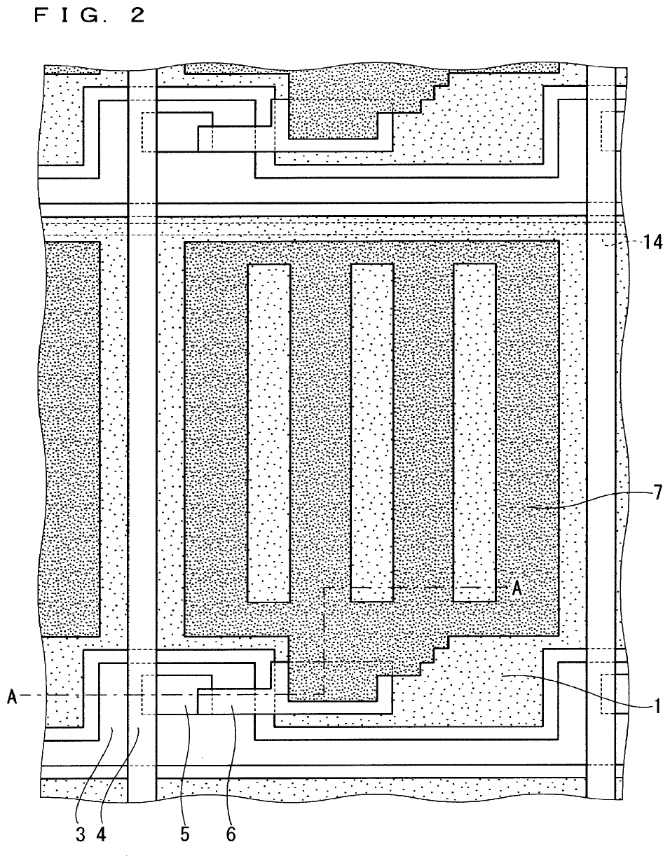

The other is a method using the light shielding layer connection line 14 illustrated in FIG. 1. FIG. 2 shows an example of a structure in which the light shielding layer connection line 14 and the absorption layer 1 are connected to each other. The absorption layer connection line 14 is made of the same material as the gate electrode 3 and disposed in the same layer as the gate electrode 3. In addition, the light shielding layer connection line 14 has a shape extending in the same direction as the gate line 13, and is disposed to overlap and contact with a partial region of the absorption layer 1. In the region where both overlap, the absorption layer 1 is disposed in the upper layer, and the absorption layer 1 and the light shielding layer connection line 14 are electrically connected to each other. Further, an electrically connected extraction electrode (not shown) through a contact hole on the light shielding layer connection line 14 is formed in a terminal part defined in the frame region 23 or the like, and the extraction electrode and the light shielding layer connection line 14 are connected to each other.

With this configuration, when the resistance of the absorption layer 1 is relatively high, a voltage is applied to the absorption layer 1 from the light shielding layer connection line 14 which has a low resistance and a small voltage drop. Therefore, voltage variations of the absorption layer 1 in the substrate surface can be reduced, and as a result, color unevenness in liquid crystal display in the substrate can be reduced.

In addition, reduction in resistance in a partial region of the absorption layer 1 is also effective as a measure against such color unevenness in liquid crystal display. For example, a low resistance region is formed in a part of the absorption layer 1 extending in the same direction as the gate line 13. As a method for forming the low resistance region, a large amount of hydrogen is injected into a region of the absorption layer 1 where the reduction in resistance is desired, so as to form a region where the hydrogen concentration is higher than the other regions in the absorption layer 1.

With this process, a low resistance region is formed in a part of the absorption layer 1, and the formed region can function similarly to the light shielding layer connection line 14. Therefore, it is not necessary to extend the light shielding layer connection line 14 throughout the pixel region, whereby the area occupied by the light shielding layer connection line 14 in the pixel region can be reduced. As a result, light from a backlight is not blocked by the light shielding layer connection line 14, and thus, the aperture ratio can be increased, and the display performance can be improved.

### First Embodiment

The thin film transistor according to the first embodiment of the present invention and the configuration of the thin film transistor substrate will be described. Note that, in the following, the case where the thin film transistor is applied to a typical TFT structure called a back channel etching structure will be described as an example.

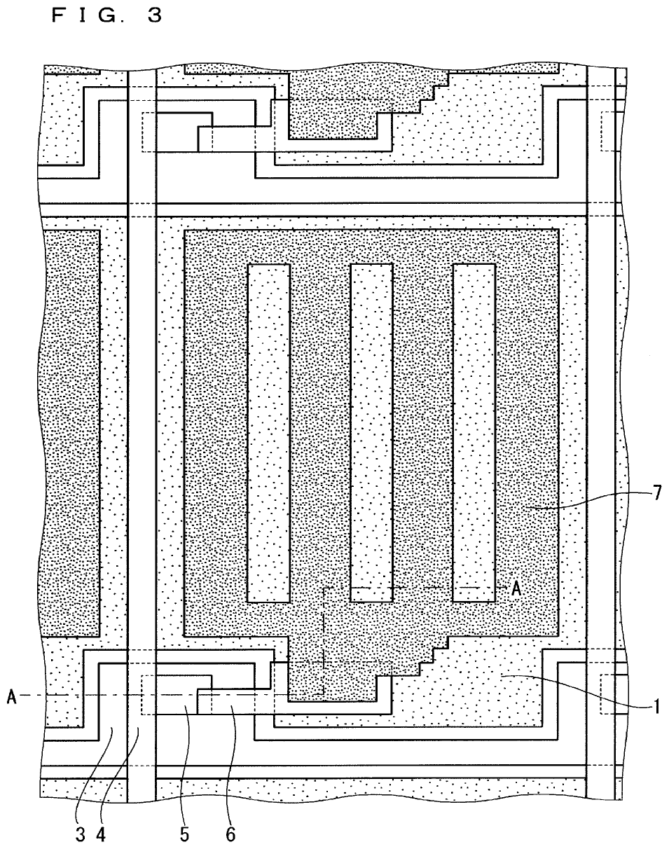

FIG. 3 is a plan view showing an example of the configuration of a liquid crystal display apparatus including the thin film transistor substrate according to the first embodiment, and illustrates a pixel portion of a TFT array substrate in the liquid crystal display apparatus. Note that the TFT array substrate is a substrate corresponding to the TFT substrate 100 in FIG. 1 and may be referred to as an “array substrate” in the following description.

The liquid crystal display apparatus generally includes a liquid crystal panel (not shown) having a structure in which a liquid crystal layer is sandwiched between an array substrate and a counter substrate, a driving printed board (not shown) connected to the liquid crystal panel, and a backlight unit (not shown). Gate lines 13 (FIG. 1) and source lines 12 (FIG. 1) are arranged in a matrix on a substrate of the array substrate, and as shown in FIG. 3, a pixel TFT 30 which is a thin film transistor is disposed at the intersection between a gate electrode 3 which is a portion of the gate lines 13 and a source electrode 4 which is a portion of the source lines 12.

The backlight is disposed on the opposite surface of the array substrate from the counter substrate, that is, on the lower surface of the array substrate. The white backlight used in the liquid crystal display apparatus has a spectrum shown in FIG. 4 as an example. The spectrum in FIG. 4 has a peak near a wavelengths of 450 to 460 nm.

Referring back to FIG. 3, the absorption layer 1 is provided on the side of the gate electrode 3, the active layer 5 of the thin film transistor is provided on the gate electrode 3, and the source electrode 4 and the drain electrode 6 are provided on the active layer 5 so as to be separated from each other. The drain electrode 6 is connected to the pixel electrode 7 which is a transparent electrode through a contact hole not shown in FIG. 3. The pixel electrode 7 may have a comb shape or a slit shape, and FIG. 3 shows an example in which the pixel electrode 7 has a comb shape.

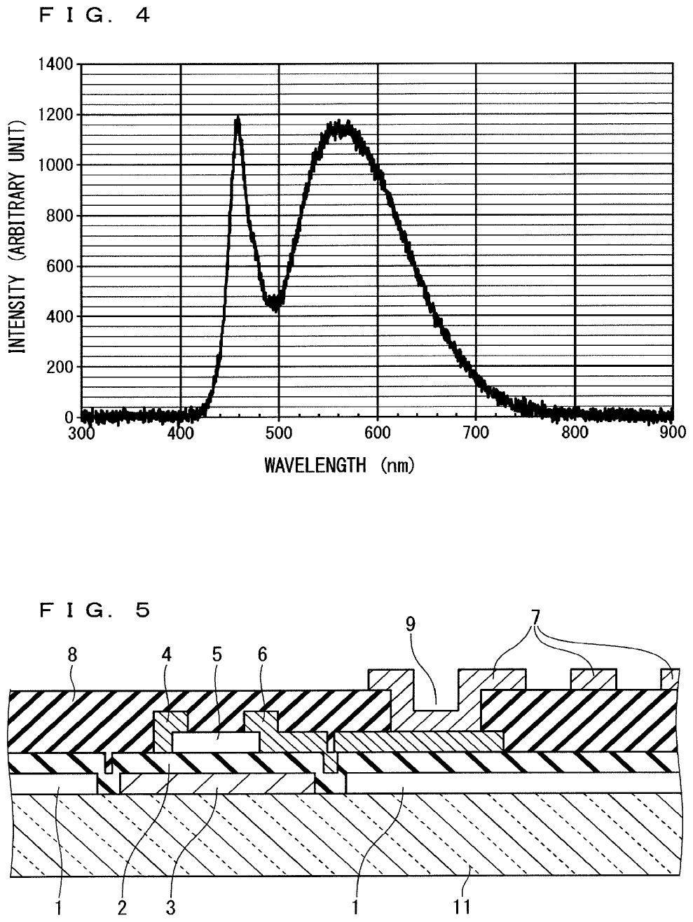

FIG. 5 is a sectional view, along a line A-A in FIG. 3, showing an example of the configuration of the array substrate according to the first embodiment. The array substrate includes the absorption layer 1, a gate insulating film 2, the gate electrode 3, the source electrode 4, the active layer 5, the drain electrode 6, the pixel electrode 7, a protective insulating film 8, and a substrate 11.

The gate electrode 3 is disposed on the substrate 11. The substrate 11 is a light-transmissive insulating substrate such as a glass substrate or a quartz substrate. The gate electrode 3 contains a metal material such as aluminum. Note that the gate electrode 3 may have a multilayer structure including a material of another composition on both of or either one of the upper and lower surfaces.

The absorption layer 1 is disposed on the substrate 11 so as to be separated from the gate electrode 3. The absorption layer 1 contains an oxide semiconductor.

The gate insulating film 2 is disposed on the gate electrode 3 and the absorption layer 1 so as to cover the gate electrode 3 and the absorption layer 1. The gate insulating film 2 is composed of a single layer including any one of insulating materials, such as a silicon oxide film, a silicon nitride film, a silicon oxynitride film, and an alumina film, or a multilayer structure including a plurality of these films.

The active layer 5 is disposed on the gate insulating film 2 and overlaps with the gate electrode 3 in plan view. The active layer 5 contains an oxide semiconductor.

The source electrode 4 is disposed on the upper part and on the lateral part of the active layer 5 on one end part, and is connected to the one end part of the active layer 5. The drain electrode 6 is disposed on the upper part and on the lateral part of the active layer 5 on the other end part, and is connected to the other end part of the active layer 5. The source electrode 4 and the drain electrode 6 are separated from each other. The source electrode 4 and the drain electrode 6 include a metal such as molybdenum, titanium, or aluminum, or a laminated film of these metals.

The protective insulating film 8 is disposed on the source electrode 4, the active layer 5, and the drain electrode 6. In the first embodiment, the protective insulating film 8 covers the source electrode 4 and the active layer 5, and covers the drain electrode 6 except for the contact hole 9 provided on a part of the drain electrode 6. The protective insulating film 8 is disposed to suppress moisture and the like entering from the outside, and includes a silicon oxide film, a silicon nitride film, alumina, and the like.

The pixel electrode 7 connected to the drain electrode 6 through the contact hole 9 is disposed on the insulating film. In the first embodiment, the insulating film includes the gate insulating film 2 and the protective insulating film 8.

Here, in the conventional configuration, light which is from the backlight and is reflected at the interface between the layers through the gap between the gate electrodes is incident on the active layer 5. On the other hand, according to the array substrate in the first embodiment, the absorption layer 1 is disposed at the entrance where light enters between the gate electrodes 3, and light harmful to the thin film transistor can be effectively absorbed by the absorption layer 1, whereby fluctuations in the characteristics of the thin film transistor can be suppressed. Further, the pixel electrode 7 is disposed above the absorption layer 1, and the pixel electrode 7 and the absorption layer 1 are insulated from each other by the gate insulating film 2 and the protective insulating film 8. Therefore, an electric field can be applied to the pixel electrode 7 by applying a voltage to the absorption layer 1.

Further, in the first embodiment, since the pixel electrode 7 has a comb shape or a slit shape, the absorption layer 1 can be used as a common electrode. That is, by applying a voltage to both the absorption layer 1 and the pixel electrode 7, an electric field can also be formed above the pixel electrode 7. Due to this electric field, the alignment of the liquid crystal layer located in the upper layer of the pixel electrode 7 can be controlled, whereby on-off control of the liquid crystal display can be performed. Furthermore, a mask for forming the absorption layer 1 and the common electrode can be reduced by utilizing the absorption layer 1 also as the common electrode. As a result, an increase in the number of masks used in the entire manufacturing process can be suppressed, which can suppress an increase in cost.

Note that the pixel electrode 7 does not necessarily have a comb shape or a slit shape. For example, in a case where the pixel electrode 7 is configured to have a shape other than a comb shape or the like, the absorption layer 1 can be used as an electrode for the storage of charges in the pixel electrode 7, as described in the third embodiment to be described later. In this case, a leakage in an off-state of the TFT is reduced, whereby the characteristics of the TFT can be improved.

It is to be noted that, as shown in FIG. 3, the absorption layer 1 is disposed to surround the gate electrode 3, and as shown in FIG. 5, the gate insulating film 2 is provided between the absorption layer 1 and the gate electrode 3. In such a configuration, if the distance between the gate electrode 3 and the absorption layer 1 is reduced, the suppression of light incidence on the active layer 5 can be enhanced. When wet etching is used, the distance between the gate electrode 3 and the absorption layer 1 is, for example, about 3 μm, and this distance depends on the processing accuracy of the process. For example, in a case where microfabrication using a dry etching technique is possible, the distance between the gate electrode 3 and the absorption layer 1 can be made smaller than that formed by wet etching.

It is to be noted, however, that, in a case where ensuring the light intensity of the display is given priority over the suppression of light incidence on the active layer 5, the distance between the absorption layer 1 and the gate electrode 3 may be relatively increased by relatively reducing the area of the absorption layer 1. In particular, in the pixel region for blue display, it is preferable that the light intensity is ensured by relatively reducing the area of the absorption layer 1.

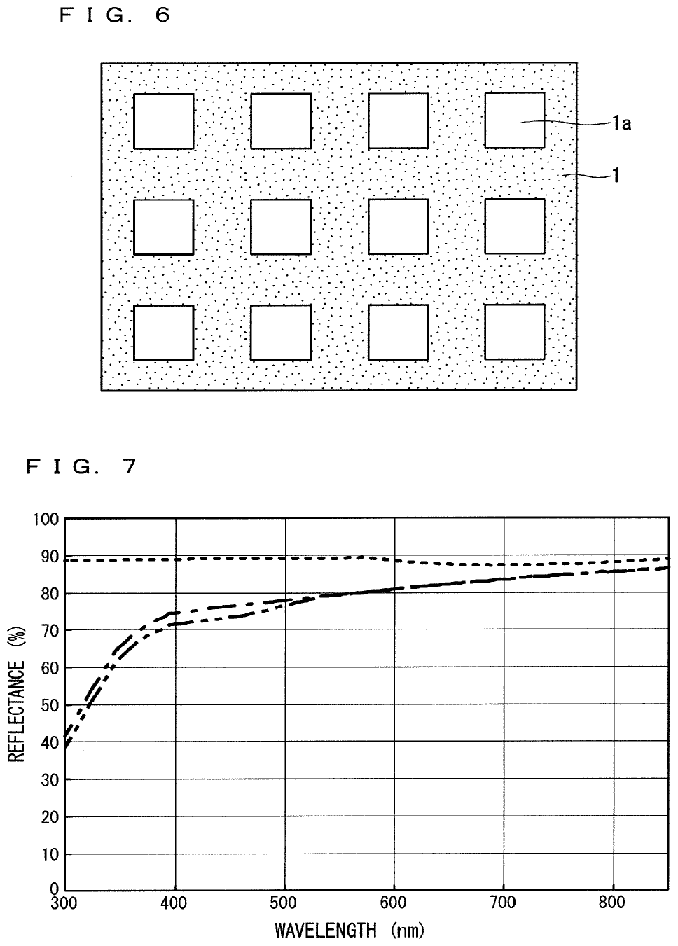

In addition, as shown in FIG. 6, holes 1a may be partially provided in the absorption layer 1. The shape of each hole 1a may be any of a square, a rectangle, a circle, an ellipse, a polygon, and the like, and may be determined in accordance with the shape of the liquid crystal display apparatus. According to such a configuration, light intensity can be ensured.

Meanwhile, in the first embodiment, the oxide semiconductor of the absorption layer 1 contains a metal element same as the metal element of the oxide semiconductor of the active layer 5. The metal composition ratio of the metal element of the absorption layer 1 is the same as the metal composition ratio of the metal element of the active layer 5. As the oxide semiconductor of the absorption layer 1 and the active layer 5, an oxide semiconductor containing at least one of In, Ga, and Zn, for example, an InGaZnO-based oxide semiconductor, may be used. However, the present invention is not limited thereto, and the absorption layer 1 and the active layer 5 may contain, for example, Sn, Al, and B.

According to the configuration described above, the same kind of defect level in the band gap is formed at the same energy position. As a result, harmful light contained in the light from the backlight and to be absorbed by the active layer 5 can be selectively absorbed in advance by the absorption layer 1, so that fluctuations in the characteristics of the thin film transistor can be suppressed. In addition, light which does not affect the characteristic fluctuation of the thin film transistor is transmitted, and the light intensity can be ensured, whereby deterioration in display performance can be suppressed.

FIG. 7 is a diagram showing an example of reflectance characteristics of the InGaZnO film disposed on an Al film. The dotted line in the drawing indicates the reflectance characteristics of the Al film, the alternate long and short dash line indicates the reflectance characteristics of the InGaZnO film, and the alternate long and two short dashes line indicates the reflectance characteristics of an InGaZnO film having a relatively high H content. Hereinafter, the InGaZnO film having a relatively high H content may be referred to as a hydrogen-containing InGaZnO film.

From the reflectance characteristics in FIG. 7, both the InGaZnO film and the hydrogen-containing InGaZnO film decrease in reflectance toward shorter wavelength from about 500 nm. It is understood from the above that the absorptivity of the InGaZnO film is increased toward shorter wavelength from about 500 nm. In addition, it is found that the hydrogen-containing InGaZnO film absorbs more light than the InGaZnO film within a shorter wavelength range from about 500 mm.

The absorption at a wavelength of about 500 nm to 400 nm is attributable to the fact that defect levels in the band gap of the InGaZnO film absorb light. When the defect level of the active layer 5 absorbs light as described above, fluctuations or deterioration of the characteristics of the thin film transistor may occur. In view of this, in the first embodiment, the absorption of light by the active layer 5 is suppressed by the absorption layer 1 absorbing the light contributing to the excitation of the defect level in advance as described above, whereby deterioration of the thin film transistor can be suppressed. Here, based on the characteristics in FIG. 7, the content of hydrogen in the absorption layer 1 is preferably greater than the content of hydrogen in the active layer 5. According to such a configuration, the effect of selectively absorbing light harmful to the active layer 5 by the absorption layer 1 can be enhanced.

Note that the content of oxygen in the absorption layer 1 may be greater than the content of oxygen in the active layer 5. With this configuration, the band gap of the absorption layer 1 can be widened, whereby the transmittance of the absorption layer 1 at the short wavelength side is improved. For this reason, light harmful to the active layer 5 can be less likely to be absorbed by the active layer 5.

In addition, as the film thickness of the absorption layer 1 increases, the amount of light absorbed by the absorption layer 1 increases exponentially. Therefore, when the film thickness of the active layer 5 is, for example, about 50 nm, the film thickness of the absorption layer 1 may be adjusted to be thick if an emphasis is placed on absorption and may be adjusted to be thin if an emphasis is placed on transmittance, within a range from 10 nm to 500 nm, for example.

<Manufacturing Method>

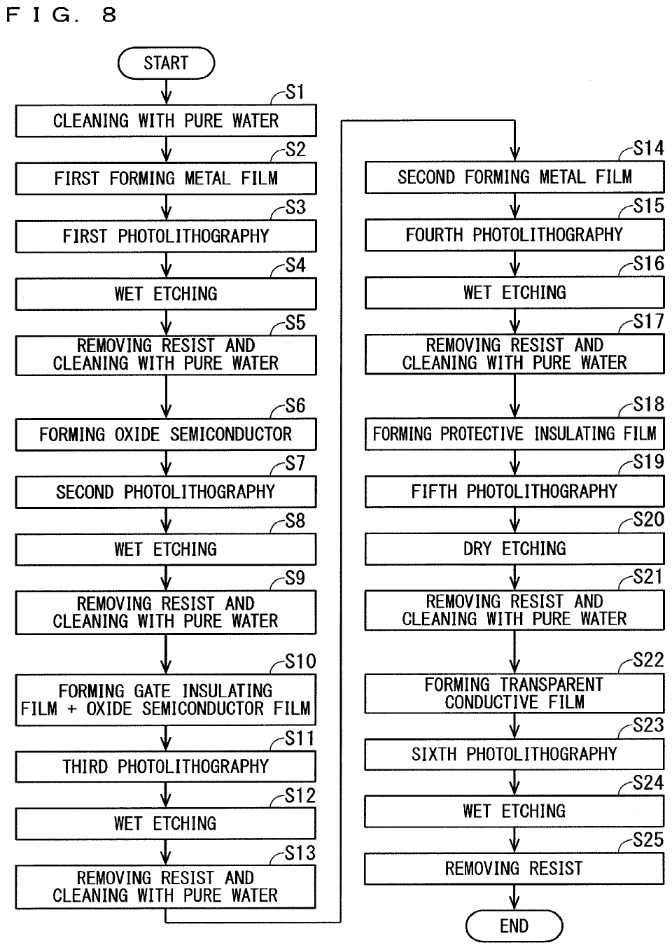

Next, a method for manufacturing the array substrate according to the first embodiment will be described. FIG. 8 is a flowchart showing an example of the method for manufacturing the array substrate according to the first embodiment. Note that resist application and patterning described in the present specification are described as photolithography in FIG. 8. Further, resist removal described in the present specification is described as removing resist and cleaning with pure water in FIG. 8.

First, in step S1, the substrate 11 is cleaned with pure water. A metal film made of, for example, aluminum is formed on the substrate 11 in step S2, and then, a resist is applied and patterned in step S3. Then, in step S4, the metal film is wet etched using the resist as a mask, and then, in step S5, the resist is removed to form the gate electrode 3. The thickness of the gate electrode 3 is, for example, about 200 nm.

Next, in step S6, an oxide semiconductor is formed in a region of the substrate 11 in which the gate electrode 3 is not formed, and then, a resist is applied and patterned in step S7. Then, in step S8, the oxide semiconductor film is wet etched using the resist as a mask, and then, in step S9, the resist is removed to form the absorption layer 1 separated from the gate electrode 3 on the substrate 11.

In the first embodiment, an oxide semiconductor which is transparent to visible light and contains at least one of In, Ga, and Zn, such as an InGaZnO-based oxide semiconductor, is formed as an oxide semiconductor film serving as the absorption layer 1, for example. A sputtering method is used to form the InGaZnO film serving as the absorption layer 1. A target including InGaZnO with a composition ratio of In:Ga:Zn=1:1:1 is used as a target, for example. The sputtering method is performed under a condition in which, for example, a direct current (DC) power is 100 W to 1000 W, a substrate temperature is 25° C. to 300° C., a pressure is 0.1 Pa to 1.0 Pa, and a ratio of O₂ to the total pressure in an Ar atmosphere is 1% to 20%.

Note that the H concentration in the InGaZnO film can be controlled to be between 10 atoms % and 0.1 atoms % by controlling and adjusting the water partial pressure, that is, the H₂O pressure, to be 5E-3 Pa to 5E-5 Pa. At this time, the hydrogen content in the InGaZnO film can be increased as the value of the H₂O pressure during the formation of the InGaZnO film is greater.

Therefore, in the first embodiment, the absorption layer 1 is formed by the sputtering method using a target which is the same in metal element composition ratio as a target used for forming the active layer 5 described later. Then, the absorption layer 1 is formed under a state where a water partial pressure is higher than a water partial pressure during the formation of the active layer 5 described later. Thus, the content of hydrogen in the absorption layer 1 can be made greater than the content of hydrogen in the active layer 5. Therefore, the effect of selectively absorbing light harmful to the active layer 5 by the absorption layer 1 can be enhanced.

In addition, the oxygen content in the InGaZnO film can be increased as the ratio of O₂ relative to the Ar pressure during the formation of the InGaZnO film is increased. Therefore, in the first embodiment, the absorption layer 1 is formed under a state where an oxygen partial pressure is higher than an oxygen partial pressure during the formation of the active layer 5 described later. Thus, the content of oxygen in the absorption layer 1 can be made greater than the content of oxygen in the active layer 5. Therefore, the band gap of the absorption layer 1 can be widened, and the transmittance of the absorption layer 1 on the short wavelength side is improved, so that light harmful to the active layer 5 can be less likely to be absorbed by the active layer 5.

Next, in step S10, the gate insulating film 2 is formed to cover the gate electrode 3 and the absorption layer 1. The gate insulating film 2 is formed as a silicon nitride film, a silicon oxide film, an alumina film, or a laminated film of such films by using a CVD (Chemical Vapor Deposition) method or a sputtering method. The total film thickness of the gate insulating film 2 is, for example, about 200 to 600 nm.

Next, an InGaZnO film which is an oxide semiconductor is formed to have a thickness of, for example, about 50 nm on the gate insulating film 2 by a sputtering method. As described above, in the first embodiment, the absorption layer 1 is formed by the sputtering method using a target which is the same in metal element composition ratio as the target used for forming the active layer 5 described later. Thus, the metal element contained in the oxide semiconductor of the absorption layer 1 and the metal element contained in the oxide semiconductor of the active layer 5 can be the same, and the same kind of defect level in the band cap is formed at the same energy position. As a result, fluctuations in the characteristics of the thin film transistor can be suppressed, and a decrease in display performance can be suppressed.

Note that, as the content of hydrogen in the active layer 5 is smaller, the number of defect levels causing the characteristic deterioration in the band gap is reduced, and the characteristic deterioration of the thin film transistor is less likely to occur. Therefore, it is preferable to reduce the content of hydrogen in the active layer 5 as much as possible by minimizing the water partial pressure during the formation of the active layer 5.

Thereafter, in step S11, a resist is applied and patterned. Then, in step S12, the InGaZnO film is wet etched using the resist as a mask, and then, in step S13, the resist is removed to form the active layer 5. The thickness of the gate electrode 3 is, for example, about 200 nm. Note that dry etching may be used instead of wet etching for etching the InGaZnO film.

After a metal film made of, for example, titanium, aluminum, molybdenum, or the like is formed on the gate insulating film 2 and the active layer 5 in step S14, a resist is applied and patterned in step S15. Then, in step S16, the metal film is wet etched using the resist as a mask, and then, in step S17, the resist is removed to form the source electrode 4 and the drain electrode 6. The source electrode 4 is connected to one side of the active layer 5, the drain electrode 6 is connected to the other side of the active layer 5, and the source electrode 4 and the drain electrode 6 are separated from each other. Dry etching may be used instead of wet etching for etching the source electrode 4 and the drain electrode 6. Gas species and etchants for dry etching are appropriately selected according to the material of the source electrode 4 and the like.

In step S18, the protective insulating film 8 is formed to cover the surfaces of the active layer 5, the source electrode 4, and the drain electrode 6. A silicon oxide film is formed as the protective insulating film 8 by CVD. The silicon oxide film is formed to have a thickness of about 100 nm. Similarly, a silicon oxide film (organic film) containing an organic substance is formed thereon as the protective insulating film 8 by a coating method. A slit coater or a spin coater is used for the coating method. The upper surface of the protective insulating film 8 can be planarized by using a coating method.

When a photosensitive resin is used for this organic film, the number of processes is advantageously decreased. The thickness of the organic film is, for example, about 1.5 μm. Note that a silicon nitride film may be laminated on the silicon oxide film formed by CVD. Due to the formation of the silicon nitride film, an influence of moisture on the thin film transistor can be suppressed. Any insulator such as a silicon nitride film as well as a silicon oxide film may be used for the protective insulating film 8.

In step S19, a resist is applied and patterned. Then, in step S20, the protective insulating film 8 on the drain electrode 6 is dry etched, and then, in step S21, the resist is removed to form a contact hole 9.

In step S22, a transparent conductive film such as an ITO film (film containing In, Sn, and O) is formed on the inner wall of the contact hole 9 and on the protective insulating film 8 by the sputtering method or the like, and then, in step S23, a resist is applied and patterned. Then, after the ITO film is wet etched in step S24, the resist is removed to form the pixel electrode 7 in step S25.

In the first embodiment, the pixel electrode 7 having a comb shape is formed by the patterning described above. In addition, the pixel electrode 7 is formed on the insulating film including the gate insulating film 2 and the protective insulating film 8 and above the absorption layer 1. Note that the material of the pixel electrode 7 is not limited to the abovementioned elements, and may be those, such as an oxide semiconductor, which has a conductive property of transmitting a visible region, such as InZnO, InO, or ZnO, as well as ITO.

In the display apparatus including the array substrate configured as described above according to the first embodiment, the absorption layer 1 can be used as a common electrode, and an electric field can be formed above the pixel electrode 7, by applying a voltage to the absorption layer 1 and the pixel electrode 7. Note that the state in which a voltage is applied to the pixel electrode 7 can be achieved by applying an appropriate voltage to the gate electrode 3 and the source electrode 4 and supplying charges to the pixel electrode 7.

Note that the extraction electrode for applying a voltage to the absorption layer 1 can be fabricated as follows. Simultaneously with the formation of the contact hole 9, another contact hole (not shown) is formed in the gate insulating film 2 and the protective insulating film 8 on the absorption layer 1 in a terminal part defined in a region other than the display region 24 (FIG. 1), that is, in the frame region 23, for example. Next, the extraction electrode electrically connected to the absorption layer 1 through the other contact hole is formed on the protective insulating film 8 in the terminal part simultaneously with the patterning of the pixel electrode 7. In this manner, the configuration such as the extraction electrode for applying a voltage to the absorption layer 1 can be fabricated in parallel with the fabrication of the configuration of the display region 24 without adding a new step.

### Summary of First Embodiment

The array substrate according to the first embodiment as described above includes: the substrate 11; the gate electrode 3 disposed on the substrate 11; the absorption layer 1 disposed on the substrate 11 so as to be separated from the gate electrode 3 and containing an oxide semiconductor; and the gate insulating film 2 disposed on the gate electrode 3 and the absorption layer 1. The array substrate includes: the active layer 5 which is disposed on the gate insulating film 2, overlaps with the gate electrode 3 in plan view, and contains an oxide semiconductor; the source electrode 4 and the drain electrode 6, each connected to the active layer 5; the protective insulating film 8 disposed on the active layer 5, the source electrode 4, and the drain electrode 6; and the pixel electrode 7 disposed on an insulating film that includes the gate insulating film 2 and the protective insulating film 8, and above the absorption layer 1, the pixel electrode 7 being connected to the drain electrode 6.

According to the configuration as described above, the absorption layer 1 is provided, whereby, for example, light of a wavelength harmful to the active layer 5 in the light from the backlight incident on the active layer 5 can be absorbed by the absorption layer 1. Therefore, it is possible to prevent light of a harmful wavelength from reaching the active layer 5. In addition, since the absorption layer 1 can absorb only the wavelength harmful to the active layer 5, the light intensity can be ensured, and the influence on the display performance can be reduced.

### Second Embodiment

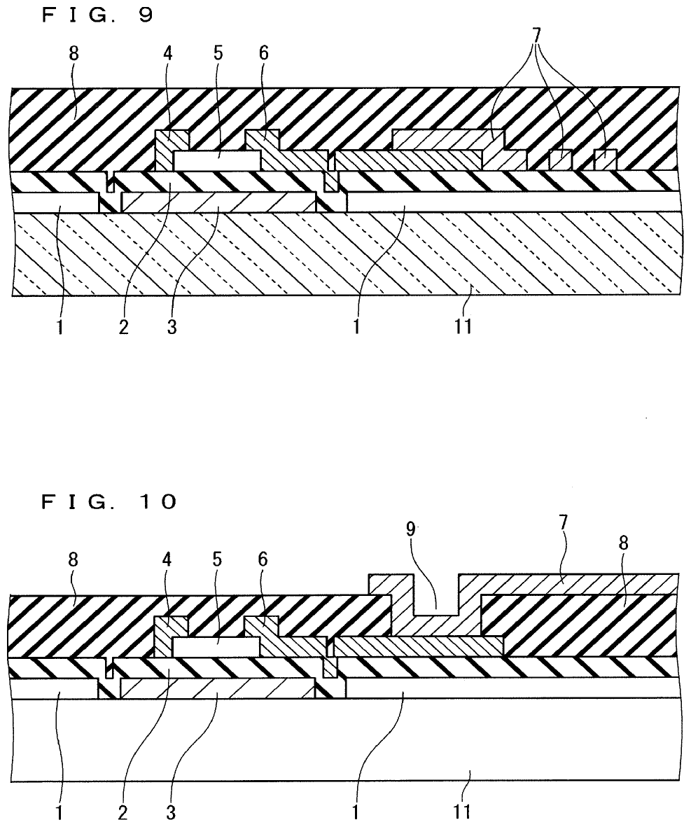

FIG. 9 is a sectional view showing an example of the configuration of an array substrate according to the second embodiment of the present invention. Hereinafter, the components in the second embodiment same or similar to the abovementioned components are identified by the same reference signs, and different components will be mainly described.

In the first embodiment described above, the structure in which the pixel electrode 7 is disposed on the insulating film including the gate insulating film 2 and the protective insulating film 8 has been described. On the other hand, in the second embodiment, the pixel electrode 7 is disposed on an insulating film including the gate insulating film 2 without including the protective insulating film 8, as shown in FIG. 9. That is, the insulating film between the pixel electrode 7 and the absorption layer 1 is only the gate insulating film 2. According to such a configuration, the distance between the absorption layer 1 and the pixel electrode 7 is determined by the film thickness of the gate insulating film 2 alone, so that the control of the distance is easy and variations in the distance in a plane can be reduced. Therefore, variations in display performance in the plane can be reduced.

Next, a method for manufacturing the array substrate according to the second embodiment will be described. In the second embodiment, the processes from step S1 to step S17 in FIG. 8 are performed to form the source electrode 4 and the drain electrode 6, as in the first embodiment.

Thereafter, a transparent conductive film such as an ITO film (film containing In, Sn, and O) is formed to cover the surfaces of the active layer 5, the source electrode 4, and the drain electrode 6, and then, a resist is applied and patterned. Then, after the ITO film is wet etched, the resist is removed to form the pixel electrode 7. The pixel electrode 7 configured in this way is connected to the drain electrode 6. Further, the pixel electrode 7 is disposed on the insulating film including only the gate insulating film 2 and above the absorption layer 1, and has a comb shape.

Next, the protective insulating film 8 is formed on the source electrode 4, the active layer 5, the drain electrode 6, and the pixel electrode 7.

Although not shown, the gate insulating film 2 and the protective insulating film 8 on the absorption layer 1 are etched to form a contact hole that exposes the absorption layer 1 in a terminal part defined in a region other than the display region 24 (FIG. 1) that is, the frame region 23, for example.

### Summary of Second Embodiment

In the array substrate according to the first embodiment as described above, the insulating film under the pixel electrode 7 includes the gate insulating film 2 without including the protective insulating film 8. According to the configuration described above, variations in the distance between the absorption layer 1 and the pixel electrode 7 in a plane can be reduced. Therefore, excellent display performance with less variations in the plane can be obtained with a high light-shielding effect on the active layer 5 being achieved.

### Third Embodiment

FIG. 10 is a sectional view showing an example of the configuration of an array substrate according to the third embodiment of the present invention. Hereinafter, the components in the third embodiment same or similar to the abovementioned components are identified by the same reference signs, and different components will be mainly described.

The first and second embodiments have described the case where the absorption layer 1 is used as a common electrode by forming the pixel electrode 7 into a comb shape or the like. On the other hand, in the third embodiment, the absorption layer 1 is used as a storage capacitor electrode. For this reason, in the third embodiment, it is not necessary to form the pixel electrode 7 into a comb shape or the like.

Next, a method for manufacturing the array substrate according to the third embodiment will be described. In the third embodiment, the processes from step S1 to step S22 in FIG. 8 are performed to form a transparent conductive film such as an ITO film on the inner wall of the contact hole 9 and on the protective insulating film 8, as in the first embodiment. Thereafter, the pixel electrode 7 is formed on the insulating film including the gate insulating film 2 and the protective insulating film 8 and above the absorption layer 1. At this time, it is not necessary to form the pixel electrode 7 into a comb shape or the like.

In a TN (Twisted Nematic) structure or a VA (Vertical Alignment) structure, the pixel electrode 7 is used as a lower electrode which forms an electric field in a liquid crystal layer with an upper electrode. The on-off control of the liquid crystal display can be performed by controlling the electric field. According to this structure, a liquid crystal display with a high production margin or high contrast can be achieved.

### Summary of Third Embodiment

Since the absorption layer 1 is disposed below the insulating film and under the absorption layer 1, the charge holding performance of the pixel electrode 7 can be improved by applying a voltage to the absorption layer 1. That is, the absorption layer 1 can be used as a charge holding electrode of the pixel electrode 7.

Conventionally, a metal similar to that of the gate electrode is used for the charge holding electrode, which leads to a reduction in transmittance. In order to prevent such reduction, the charge holding electrode having a large area on a plane cannot be formed, resulting in that the capacitance between the charge holding electrode and the pixel electrode cannot be increased.

On the other hand, in the third embodiment, a larger capacitance can be formed between the pixel electrode 7 and the absorption layer 1 by using the transparent absorption layer 1 which can be formed to have a large area as the charge holding electrode. For this reason, the charge holding characteristics of the pixel electrode 7 and the characteristics of the thin film transistor can be improved, while the reduction in the light transmittance is suppressed.

In order to use as an FFS (fringe field switching) structure, an interlayer insulating film (not shown) may be formed on the pixel electrode 7 after the array substrate described above is formed, an oxide semiconductor film (not shown) such as an ITO film may be formed thereon, and an electrode obtained by patterning the oxide semiconductor film to have a comb shape may be used as a common electrode. Thus, an electric field can be formed between the pixel electrode 7 and the common electrode, and control such as on-off control of the liquid crystal display can be performed.

It is to be noted that, within the scope of the present invention, the above embodiments may be freely combined with each other, or each of the above embodiments may be modified or omitted as appropriate.

While the present invention has been described in detail, the foregoing description is in all aspects illustrative and not restrictive. It is therefore understood that numerous modifications and variations can be conceived of without departing from the scope of the present invention.

### EXPLANATION OF REFERENCE SIGNS

1: absorption layer
1a: hole
2: gate insulating film
3: gate electrode
4: source electrode
5: active layer
6: drain electrode
7: pixel electrode
8: protective insulating film
11: substrate

1. A thin film transistor substrate comprising:
a substrate;
a gate electrode disposed on the substrate;
an absorption layer disposed on the substrate so as to be separated from the gate electrode and containing an oxide semiconductor;
a gate insulating film disposed on the gate electrode and the absorption layer;
an active layer disposed on the gate insulating film, overlapping with the gate electrode in plan view, and containing an oxide semiconductor;
a source electrode and a drain electrode, each connected to the active layer;
a protective insulating film disposed on the active layer, the source electrode, and the drain electrode; and
a pixel electrode disposed on an insulating film that includes the gate insulating film or the gate insulating film and the protective insulating film, and above the absorption layer, the pixel electrode being connected to the drain electrode.

2. The thin film transistor substrate according to claim 1, wherein the insulating film includes the gate insulating film without including the protective insulating film.

3. The thin film transistor substrate according to claim 1, wherein the pixel electrode has a comb shape or a slit shape.

4. The thin film transistor substrate according to claim 1, wherein the absorption layer contains a metal element same as a metal element of the active layer.

5. The thin film transistor substrate according to claim 4,
wherein a metal composition ratio of the metal element in the absorption layer is identical to a metal composition ratio of the metal element in the active layer, and
a content of hydrogen in the absorption layer is greater than a content of hydrogen in the active layer.

6. The thin film transistor substrate according to claim 5, wherein a content of oxygen in the absorption layer is greater than a content of oxygen in the active layer.

7. The thin film transistor substrate according to claim 4, wherein the absorption layer is formed with one or more holes in plan view.

8. A method for manufacturing a thin film transistor substrate, the method comprising:
forming a gate electrode on a substrate;
forming an absorption layer that is disposed on the substrate so as to be separated from the gate electrode and contains an oxide semiconductor;
forming a gate insulating film disposed on the gate electrode and the absorption layer;
forming an active layer that is disposed on the gate insulating film, overlaps with the gate electrode in plan view, and contains an oxide semiconductor;
forming a source electrode and a drain electrode, each connected to the active layer;
forming a protective insulating film disposed on the active layer, the source electrode, and the drain electrode; and
forming a pixel electrode disposed on an insulating film that includes the gate insulating film or the gate insulating film and the protective insulating film, and above the absorption layer, the pixel electrode being connected to the drain electrode.

9. The method for manufacturing a thin film transistor substrate according to claim 8, wherein the pixel electrode has a comb shape or a slit shape.

10. The method for manufacturing a thin film transistor substrate according to claim 8, wherein the absorption layer is formed by a sputtering method using a target that is same in metal element composition ratio as a target used for forming the active layer.

11. The method for manufacturing a thin film transistor substrate according to claim 10, wherein the absorption layer is formed under a state where a water partial pressure is higher than a water partial pressure during formation of the active layer.

12. The method for manufacturing a thin film transistor substrate according to claim 11, wherein the absorption layer is formed under a state where an oxygen partial pressure is higher than an oxygen partial pressure during formation of the active layer.
